(19) United States
(12) Patent Application Publication
(10) Pub. No.: US 2006/0176721 A1
(43) Pub. Date: Aug. 10, 2006

(54) Method and apparatus for managing ternary content addressable memory

(76) Inventors: Su-Young Kim, Suwon-si (KR); Jong-Sang Oh, Suwon-si (KR); Byung-chang Kang, Yongin-si (KR)

Correspondence Address: Robert E. Bushnell, Suite 300, 1522 K Street, N.W., Washington, DC, 20005-1202, US

(21) Appl. No.: 11/330,258

(22) Filed: Jan. 12, 2006

(30) Foreign Application Priority Data
Jan. 14, 2005 (KR) 2005-3887

(51) Int. Cl. G11C 15/00

(52) U.S. Cl. 365/49

(57) ABSTRACT

A method for managing a ternary content addressable memory (CAM) comprises the steps of: dividing the ternary CAM into parts corresponding to a number of sequence IDs determined by a packet classification rule set by a system manager; storing a packet having a priority set according to the packet classification rule in an entry storage area of the sequence IDs according to the priority; and, when an entry storage area allocated to a sequence ID where a new entry is intended to be added is completely occupied, extending the corresponding sequence ID and adding thereto the new entry, thereby controlling the ternary CAM.

### CLAIM OF PRIORITY

This application makes reference to, incorporates the same herein, and claims all benefits accruing under 35 U.S.C. §119 from an application for METHOD AND APPARATUS FOR MANAGING TERNARY CONTENT ADDRESS ABLE MEMORY earlier filed in the Korean Intellectual Property Office on Jan. 14, 2005 and there duly assigned Serial No. 10-2005-0003887.

### BACKGROUND OF THE INVENTION

1. Technical Field

The present invention relates to a method and apparatus for managing ternary content addressable memory, and more particularly, to a method and apparatus for managing ternary content addressable memory which method and apparatus are designed to realize packets classification or filtration by means of a ternary content addressable memory so that packets can be used in lookup with hardware.

2. Related Art

In the Internet network environment, a routing lookup operation has been a main bottleneck with respect to the performance of a network processor or router. Because of the great increase in the number of Internet users, existing class address systems have been replaced with classless interdomain routing (CIDR) systems.

Although the CIDR systems are effective with respect to IP address management, nevertheless, due to the use of longest prefix matching (LPM), routing lookup has become more difficult and complicated. Problems caused by the LPM are as follows: (i) enlarged routing table sizes; (ii) increased Internet traffic; (iii) demands for more speedy network links; and (iv) difficult migration to 128 bit IPv6 and the like. To solve these difficulties in routing lookup using the CIDR address system, hardware and software solutions have been studied.

The software solution is generally implemented by reducing memory usage, mainly by means of a compression algorithm, and then by enhancing routing lookup by means of a high speed memory, such as a cache and an SRAM. The software solution has direct benefits, including improvement in performance of microprocessors, increased hit ratio of cache, and faster front side bus (FSB). However, such a software solution has problems in that there are many algorithms to be reconstructed in their entirety when performing a routing update. Moreover, despite excellent average retrieval efficiency, the use of the software solution in the case of a complicated tree structure, results in degradation of retrieval efficiency, thereby requiring up to 32 times more memory access in the worst case.

Examples of the hardware solution generally include linear-mapping of an IP address into a memory, and use of a compression algorithm built into the hardware. The hardware solution has advantages in that routing velocity is possibly increased due to pipelining, and when run by a microprocessor, in OS porting, routing velocity is not reduced, even due to an operation or instruction.

A lookup solution which has recently become prevalent because of hardware-based construction is one using a content addressable memory (CAM). The CAM has the function of using data and retrieving an address where a value related to the data is located. The CAM is a device which is capable of implementing a comparison XOR operation in every cell, and which has an associative memory structure capable of reading and writing by means of the comparison of external information with stored contents, unlike existing random access memory (RAM) structures. With such characteristics, the CAM has been used in constructing a neural network, an image processor or a search engine in a network router.

In the CAM, information on the corresponding port and on the CAM itself may be obtained directly through one clock. Particularly, by using a ternary content addressable memory (TCAM) capable of storing undefined values (Don't Care information) rather than 0 and 1, it is possible to relatively easily provide even an LPM capability. For the purpose of packet classification, in addition to a destination IP address, a source IP address, a source/destination port number, a protocol field (5-tuple), and so on must be looked up and compared with various preset packet filtering rules at every packet. Thus, this makes the operation more complicated than IP address lookup.

TCAM conducts the parallel comparison of keys to be retrieved with all entries in CAM within a very short latency time of 10 to 20 nanoseconds, thereby allowing retrieval of a lookup result. In TCAM, there is a mask bit string corresponding to a content bit string so that it is not required that all of the content bit strings be compared with search keys, and TCAM reports or provides entry information, first-matched with the search keys among all entries in TCAM, as a retrieval result.

TCAM stores rules in sequence from high priority to low priority, and simultaneously compares the given search keys with all entries stored, thereby retrieving the first-matched entry. In course of retrieving, as previously discussed above, all content bit strings are not necessarily compared with the search keys because TCAM has a mask bit string corresponding to a content bit string.

The TCAM structure, as seen from the above, cannot however perform a function such as hot-issued packet classification or filtering. This is because the operation of comparing the stored 5-tuple information has to be conducted at every packet for the packet classification, but TCAM by its nature reports or provides only first-matched entry information. Accordingly, for packet classification or filtering, a new method of TCAM management is required.

### SUMMARY OF THE INVENTION

It is, therefore, an object of the present invention to provide a method and apparatus for managing a ternary content addressable memory, which method and apparatus identify a ternary content addressable memory using a sequence ID according to packet priority, and manage the ternary content addressable memory through partition, generation and deletion thereof, so as to perform packet classification or filtering.

To achieve the above and other objects, there is provided a method for managing a ternary content addressable memory (CAM), the method comprising the steps of: dividing the ternary CAM into parts corresponding to the number of sequence IDs determined by a packet classification rule set by a system manager; storing a packet, with a priority set according to the packet classification rule, in an entry storage area of the sequence IDs according to the priority; and, when an entry storage area allocated to a sequence ID where a new entry is intended to be added is completely occupied, extending the corresponding sequence ID area and adding thereto the new entry, thereby controlling the ternary CAM.

Preferably, all of the entries in the one sequence ID area have the same priority.

Preferably, all of the respective sequence IDs in the dividing step have the same number of entries at initialization of the ternary CAM, and the dividing step conducts the determination of sequence ID according to the packet classification rule, such that one sequence ID is matched to one packet classification rule in a one-to-one correspondence relationship.

In addition, the dividing step is so conducted as to locate a sequence ID of a smaller number at an upper layer of the ternary CAM, and the number of sequence IDs is limited depending upon the capability of the ternary CAM.

Preferably, the controlling of the ternary CAM comprises: when a new entry is added to the specific sequence ID of the ternary CAM, receiving the sequence ID input of the added packet entry dividing and determining whether the inputted sequence ID is within the range of the sequence ID provided upon the initial division of the ternary CAM; when the inputted sequence ID is determined to be within the range, determining whether an empty space exists in the inputted sequence ID where the new entry is added; and, when it is determined that there is no empty space, retrieving a compensating sequence ID having an empty entry space located in the closest proximity to the sequence ID, and adding the new entry intended to be added to the inputted sequence ID using the empty entry space in the compensating sequence ID.

Preferably, in the entry adding sub-step, when the inputted sequence ID is larger than the compensating sequence ID, all of the sequence ID areas existing in the inputted sequence ID and the compensating sequence ID are moved in sequence upward in the ternary CAM by use of the empty entry space in the area of the compensating sequence ID, and the new entry is added to an empty entry space newly generated in the inputted sequence ID area as a result of the movement.

The entry adding sub-step further comprises: when the inputted sequence ID is larger than the compensating sequence ID, sequentially moving all of the sequence ID areas existing in the inputted sequence ID and the compensating sequence ID to an upper layer of the ternary CAM by use of the empty entry space in the area of the compensating sequence ID, and adding the new entry to an empty entry space newly generated in the inputted sequence ID area as a result of the movement.

In addition, the entry adding sub-step comprises: when the inputted sequence ID is smaller than the compensating sequence ID, sequentially moving all of the sequence ID areas existing in the area between the inputted sequence ID and the compensating sequence ID to a lower layer of the ternary CAM by use of the empty entry space in the area of the compensating sequence ID, and adding the new entry to an empty entry space newly generated in the inputted sequence ID area as a result of the movement.

The controlling of the ternary CAM control step further comprises: when a packet classification rule is deleted by the system manager, deleting all of the entries in the sequence ID area corresponding to the deleted rule.

Preferably, the latter deleting step comprises: receiving the sequence ID of the added packet entry, and determining whether the inputted sequence ID is within the range that is provided in the division of the ternary CAM; and, when the inputted sequence ID is within the range, determining a location of a beginning entry of the sequence ID, deleting the corresponding entry, and then repeating the entry deletion until all of the entries in the sequence ID are completely deleted.

In accordance with another embodiment of the present invention, method for managing a ternary Content Addressable Memory (CAM), comprises the steps of: dividing the ternary CAM into parts corresponding to the number of sequence IDs determined by a packet classification rule set by a system manager; storing a packet, having a priority set according to the packet classification rule, in an entry storage area of the sequence IDs according to the priority; and, when an entry storage area allocated to a sequence ID where a new entry is intended to be added is completely occupied, retrieving a compensating sequence ID having an empty entry space located in the closest proximity to the sequence ID, moving in sequence all of the sequence ID areas existing in the inputted sequence ID and the compensating sequence ID to an upper or lower layer of the ternary CAM by use of the empty entry space in the area of the compensating sequence ID, and adding the new entry to an empty entry space newly generated in the inputted sequence ID area as a result of the movement.

In accordance with another aspect of the present invention, there is provided an apparatus for managing a ternary content addressable memory (TCAM), comprising: a TCAM hardware configuration module for initializing the ternary CAM by dividing the TCAM into parts corresponding to the number of sequence IDs determined by a packet classification rule set by a system manager; and a TCAM entry management module for storing the packet having a priority according to the packet classification rule in an entry storage area of the sequence ID according to the priority, and when an entry storage area allocated to the sequence ID where a new entry is intended to be added is completely occupied, extending the corresponding sequence ID area and adding the new entry thereto, thereby controlling the ternary CAM.

Preferably, in the TCAM hardware configuration module, all of the entries in the one sequence ID area have the same priority, and the sequence ID determination according to the packet classification rule is conducted such that one sequence ID is matched to one packet classification rule in a one-to-one correspondence relationship.

Preferably, the TCAM entry management module is such that, when a new entry is added to the specific sequence ID of the ternary CAM, the TCAM entry management module receives the sequence ID input of the added packet entry, determines whether the inputted sequence ID is within the range of the sequence ID provided upon the initial division of the ternary CAM, and determines whether an empty space where the new entry is to be added exists in the inputted sequence ID. When it is determined that there is no empty space, the TCAM entry management module retrieves a compensating sequence ID having an empty entry space located in the closest proximity to the sequence ID, and adds the new entry intended to be added to the inputted sequence ID by using the empty entry space in the compensating sequence ID.

In addition, when a packet classification rule is deleted by the system manager, the TCAM entry management module deletes all of the entries in the sequence ID area corresponding to the deleted rule.

Preferably, the TCAM entry management module deletes all of the entries in the sequence ID area by receiving the sequence ID of the added packet entry, determining whether the inputted sequence ID is within the range provided upon the division of the ternary CAM, determining a location of a beginning entry of the sequence ID and deleting the corresponding entry when the inputted sequence ID is within proper range, and repeating the entry deletion until all of the entries in the sequence ID are completely deleted.

Meanwhile, the apparatus for managing the ternary content addressable memory (TCAM) further comprises a TCAM entry lookup module for generating search keys and providing them to the ternary CAM, and for implementing lookup by using retrieval result data received from the ternary CAM in response to the generation of the search keys.

In accordance with another embodiment of the present invention, there is provided an apparatus for managing a TCAM, comprising: a TCAM hardware configuration module for initializing the ternary CAM by dividing the TCAM into parts corresponding to the number of sequence IDs determined by a packet classification rule set by a system manager; and a TCAM entry management module for storing a packet having a priority according to the packet classification rule in an entry storage area of the sequence ID according to the priority. When an entry storage area allocated to the sequence ID where a new entry is intended to be added is completely occupied, the TCAM entry management module retrieves a compensating sequence ID having an empty entry space located in the closest proximity to said sequence ID, moves in sequence all of the sequence ID areas existing in the inputted sequence ID and the compensating sequence ID to an upper or lower layer of the ternary CAM by use of the empty entry space in the area of the compensating sequence ID, and adds the new entry to an empty entry space newly generated in the inputted sequence ID area in response to the movement.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a diagram of an entry information retrieval mechanism of a ternary content addressable memory (TCAM) using the search keys and a mask;

FIG. 2 is a diagram of an apparatus for managing a TCAM table according to the present invention;

FIG. 3 is a diagram of a TCAM structure identified in dependence upon a sequence ID according to the present invention;

FIG. 4 is an operational flowchart for adding an entry to a TCAM in accordance with a method for managing a TCAM table according to the present invention;

FIG. 5 is a flowchart of a method for managing a TCAM table according to the present invention when extended entries deviate from the allocated sequence ID; and

FIG. 6 is an operational flowchart relating to deletion of an entry from a TCAM by a method for managing a TCAM table according to the present invention.

### DETAILED DESCRIPTION OF THE INVENTION

Hereinafter, the preferred embodiments of the present invention will be described in detail with reference to the drawings.

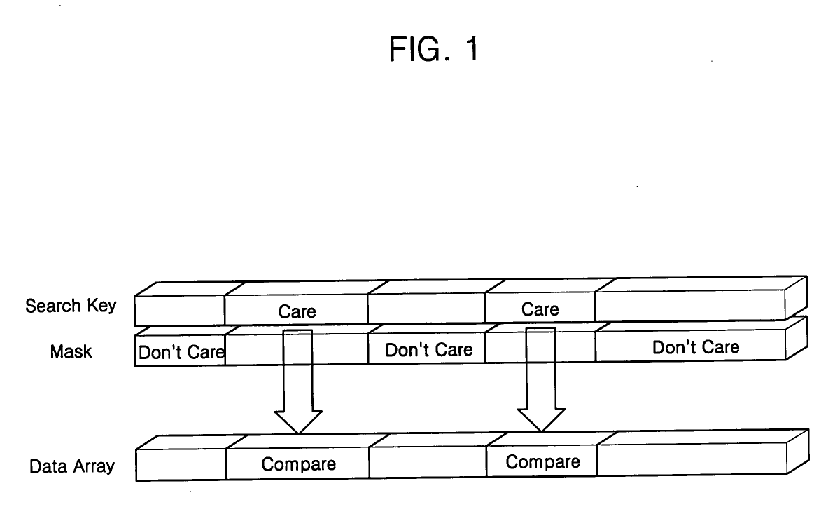

FIG. 1 is a diagram of an entry information retrieval mechanism of a ternary content addressable memory (TCAM) using the search keys and a mask.

TCAM stores rules in sequence from high priority to low priority, and simultaneously compares the given search keys with all entries stored, thereby retrieving the first-matched entry. In the course of retrieving, as previously discussed above, all of the content bit strings are not necessarily compared with the search keys because TCAM has a mask bit string corresponding to a content bit string. That is, in the event of retrieving, it is not required to consider a Don't Care portion within the mask portion of FIG. 1. ‘Compare’ of data array in FIG. 1 indicates a result obtained by comparing a portion of the search keys, except for a portion corresponding to Don't Care of the mask, with the content bit string.

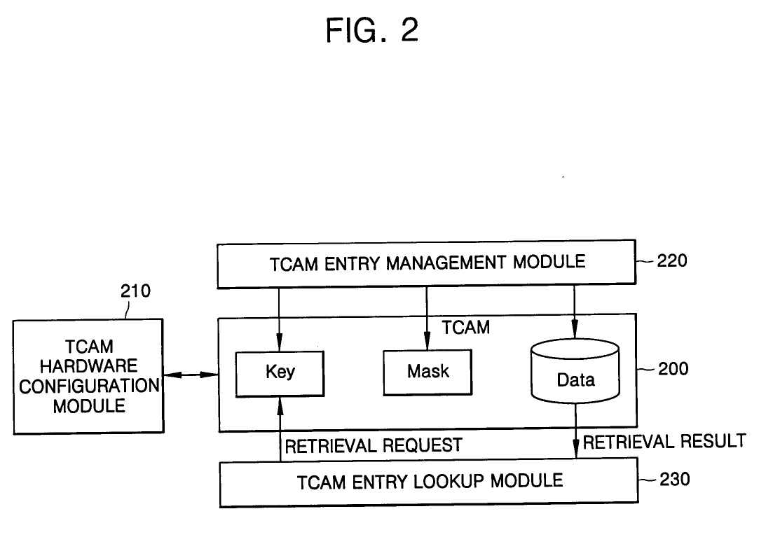

FIG. 2 is a diagram of an apparatus for managing a TCAM table according to the present invention.

The TCAM management apparatus includes a TCAM hardware configuration module 210 for managing a TCAM 200, a TCAM entry management module 220, and a TCAM entry lookup module 230.

The TCAM hardware configuration module 210 serves to initialize the TCAM 200. At initialization, an internal database of the TCAM 200 is divided into areas corresponding to a number of determined sequence IDs.

The TCAM entry management module 220 serves to generate and to add or delete TCAM entries with regard to the TCAM 200 as a simple memory. To this end, the TCAM entry management module 220 provides the TCAM 200 with search keys, a mask, and retrieval result data.

Meanwhile, the TCAM entry lookup module 230 generates the search keys and provides them to the TCAM 200. As a result, the TCAM entry lookup module 230 implements a lookup using the retrieval result data received from the TCAM 200.

Lookup can be implemented through interworking with a network processor unit (NPU) or a field-programmable gate array (FPGA), one type of programmable logic chip allowing the TCAM to be recognized as a memory, such as an SRAM.

Herein, the NPU is a software-programmable chip or chip set acting as a CPU of a computer in the network, and it serves to share a function of network connection and peripheral control that has been in charge of the CPU.

The FPGA is one type of programmable logic chip that is similar to a programmable logic device (PLD). However, the FPGA can support thousands of gates, while the PLD is generally limited to hundreds of gates.

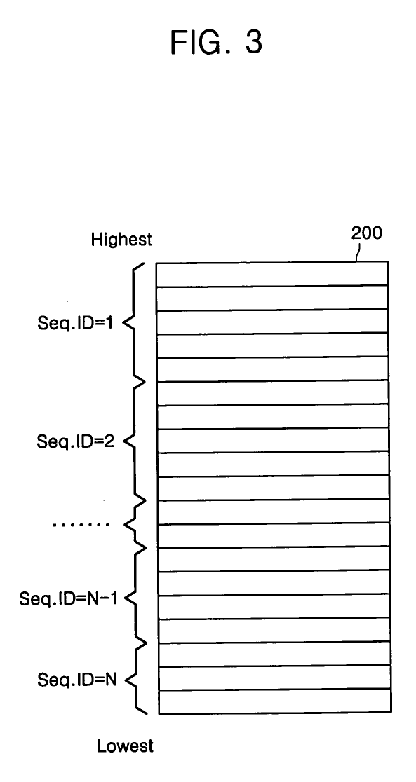

FIG. 3 is a diagram of a TCAM structure identified in dependence upon a sequence ID according to the present invention.

Since the size of the TCAM 200 is defined, the number of rules for packet filtering which are supportable in a constant size is limited. Presuming that the number of rules defined according to system capability is N, at TCAM initialization, the entire TCAM is divided into N parts, to which sequence IDs from 1 to N are provided, as shown in FIG. 3. The number of entries involved in the respective N-divided sequence IDs is identical at the initialization of the TCAM 200. The number of entries may be increased according to the respective sequence IDs.

The sequence IDs are used when the system manager determines a priority of rules, and in access of entries in the TCAM. Table 1 below illustrates a preferred embodiment of the packet classification and distribution of sequence IDs therefrom.

TABLE 1

| | | |
|---|---|---|
| Rule 1(rule ID) | Classification_rule1 | Sequence ID 1 |
| Rule 1(rule ID) | Classification_rule2 | Sequence ID 2 |
| Rule 2(rule ID) | Classification_rule1 | Sequence ID 3 |
| Rule 2(rule ID) | Classification_rule2 | Sequence ID 4 |

As shown in Table 1, several classification rules can be generated in a single rule ID, or a single classification rule can be involved in various rule IDs. Herein, for packet classification, the TCAM should include therein all of four items defined by Table 1 as entries. The identification of the respective entries is made by use of sequence IDs.

The system manager provides the respective rules with a unique sequence ID so as to allow identification between entries in the TCAM 200. TCAM 200 stores entries in the corresponding areas as divided according to the sequence IDs (see FIG. 3). Herein, the smaller the sequence IDs of entries are, the higher are the entries located in the TCAM 200, so that priority class can be maintained among the respective entries.

If the rules have variable range values for the port, various TCAM entries are generated for the single sequence ID, and they are then stored in the corresponding sequence ID area among the sequence IDs as classified in FIG. 3.

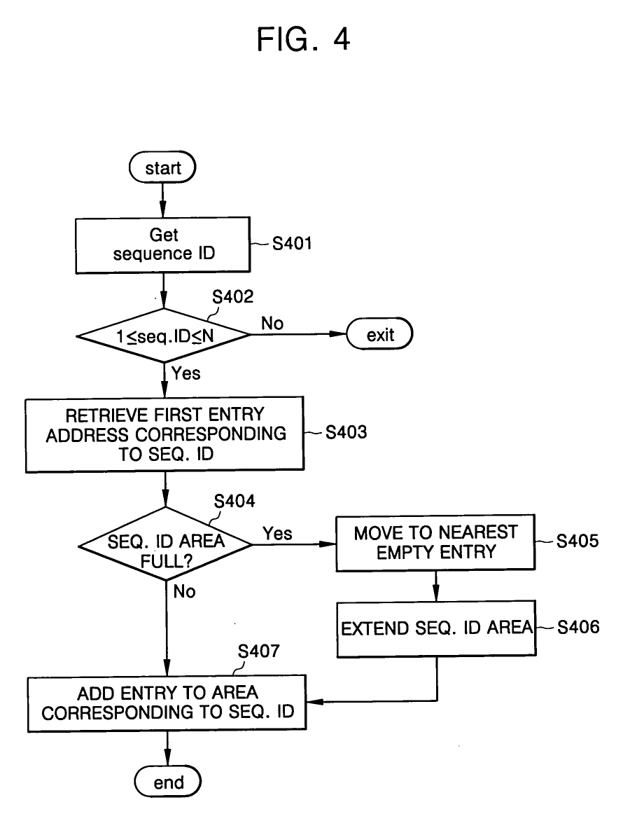

FIG. 4 is an operational flow chart for adding an entry to a TCAM in accordance with a method for managing a TCAM table according to the present invention.

First, the TCAM 200 gets a sequence ID of an added entry (S401), and determines whether the corresponding sequence ID is within the range (from 1 to N, where N is the number of all of the sequence IDs dividing the TCAM 200) provided at the initialization of TCAM 200 (S402). If not within the range, the process is terminated.

If it is determined that the sequence ID of the entry requested to be added is within the range, TCAM 200 retrieves a first entry corresponding to a corresponding sequence ID (S403). In order to make preparations for the case where entries allocated to the corresponding sequence ID have been fully occupied, a process is conducted to determine whether an empty space in the corresponding sequence ID area exists (S404). If the corresponding sequence ID area is fully occupied, a process of movement is conducted to find an empty entry positioned in the closest proximity thereto (S405), and the TCAM 200 extends an area of the corresponding sequence ID (S406). Then, TCAM 200 adds an entry to an area newly generated through the extension of the sequence ID area (S407). If the corresponding sequence ID area is not fully occupied, as determined in S404, a process is merely conducted to add a desired entry to an empty space area in the corresponding area (S407).

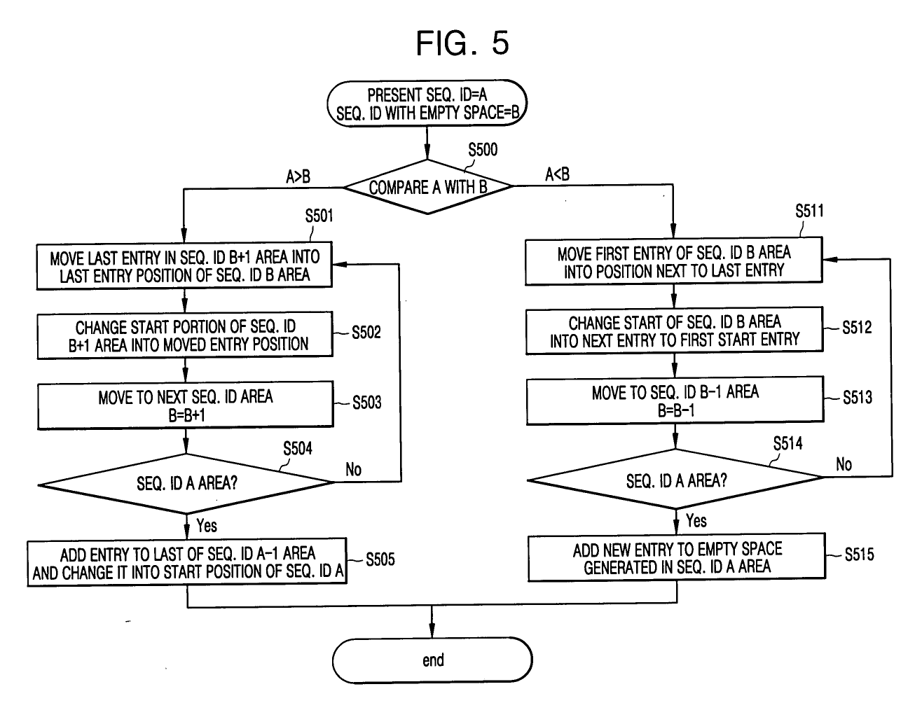

FIG. 5 is a flow chart of a method for managing a TCAM table according to the present invention when extended entries deviate from the allocated sequence ID.

That is, FIG. 5 more specifically illustrates an operational flowchart for the case, in the flowchart of FIG. 4, in which an empty space in the sequence ID area where an entry should be added does not exist (as determined at S404 of FIG. 4).

If the extended entries are over the allocated sequence ID area, a shuffling is carried out by retrieving empty entries allocated to other sequence ID areas. The shuffling uses an empty area which is in the closest proximity to the corresponding sequence ID. Since the sequence IDs determine the priority of entries, the sequence of entries corresponding to the sequence IDs should not be changed. However, since the priority is not determined separately among entries in the same sequence ID, it is not required to maintain the sequence. As explained above, this is because one sequence ID is allocated to one rule.

FIG. 5 explains an entry extension in one sequence ID with reference to two embodiments.

The first case indicates a shuffling conducted to a sequence ID area having a low value relative to that of the present sequence ID, and the second case indicates a shuffling conducted to a sequence ID area having a large value relative to that of the present sequence ID.

The present sequence ID will be referred to as ‘A,’ and the sequence ID with empty space will be referred to as ‘B.’

Since the embodiment of FIG. 5 assumes that there is no empty space in the sequence ID to which an entry to be presently added pertains, the entire circumstances are considered unless A is equal to B. If, in fact, the empty space in the sequence ID to be added exists, it would suffice to add the corresponding entry thereto so that a serious problem would not be created.

In the first step of FIG. 5, the present sequence ID A is compared to the sequence ID B with empty space (S500), and then one of two processes is conducted depending on whether the present sequence ID is larger or smaller than the sequence ID with empty space.

In the first case (A is larger than B), a process is conducted to move a last entry of the sequence ID B+1, next to the sequence ID B with empty space, to a location where a last entry of the sequence ID B with empty space had been positioned (S501). Then, a process is conducted to change a start position of the sequence ID B+1, next to the sequence ID B with empty space, into a position of the entry pertaining to the sequence ID B+1 (S502).

Once that procedure is completed, an empty space in the sequence ID B+1 area will be created. Since areas from the sequence ID B+2 to the sequence ID A have no empty space (because upon setting, the sequence ID B is already set as an area of the sequence ID with empty space in the closest proximity to the sequence ID A), such procedure should be repeated until meeting the sequence ID A. Herein, the empty space belongs to the sequence ID B+1 so that a process is conducted to substitute the sequence ID B+1 for the sequence ID B (S503), and the processes S501 and S502 are repeated.

Such procedure is repeated while monitoring to determine whether to meet an area of the sequence ID (S504). Upon approaching the area, an entry to be added to a position of the last entry of the sequence ID A−1 area is added, and this entry is changed to a start position of the sequence ID A area (S505).

Hereinafter, the first case will be explained in detail with reference to one embodiment. For example, it is intended to add an entry to an area of the sequence ID 5, presuming that the area of the sequence ID 5 has no empty space, and a shuffling is generated toward an area of the sequence ID 3 in the closest proximity to the sequence ID 5.

The last entry, among the entries corresponding to the sequence ID 4, is moved into an area exactly after the first entry (i.e., an area corresponding to the sequence ID 3, at present). The start portion of the sequence ID 4 is changed to the entry moved from the sequence ID 4 to the sequence ID 3. An entry to be added to the sequence ID 5 is added to an empty position created by the movement of the entry of the sequence ID 4 to the sequence ID 3. Finally, the start portion of the sequence ID 5 is changed to an area of the entry added.

Next, a procedure for the second case (when A is smaller than B) will be explained.

In the second case, the first entry of the sequence ID B with empty space is moved into the position next to the last entry of the sequence ID B area (S511). The position of the first entry of the sequence ID B then becomes an empty space, so that a process is conducted to change the start portion of the sequence ID B area to an entry position next to the empty space (S512). At this point, the empty space is created in the area of sequence ID B, so that a process is conducted to substitute the sequence ID B−1 for the sequence ID B (S513), and the processes S511 and S512 are repeated.

Monitoring is conducted to determine whether an area of the sequence ID A is met while repeating such procedure (S514), and a new entry to be added is added to the empty space generated in the sequence ID A (S515).

The second case where a shuffling toward a sequence ID area larger than the present sequence ID area is generated will now be explained in detail. For example, it is intended to add an entry to an area of the sequence ID 5 presuming that the area of the sequence ID 5 has no empty space and a shuffling is generated toward an area of the sequence ID 7.

First, the start entry of the sequence ID 7 is moved to the space next to the last entry (i.e., a position of the sequence ID 8 area), and the start portion of the sequence ID 7 is changed to the entry next to the original start entry. Into the empty space occupied by the start entry of the sequence ID 7 exactly before, the start entry of the sequence ID 6 is moved. In this case, the start entry of the sequence ID 6 should be also changed to the entry next to the original start entry. The space originally occupied by the start entry of the sequence ID 6 is added as a last entry of the sequence ID 5, and the extended entry to be added to the sequence ID 5 is added to this space.

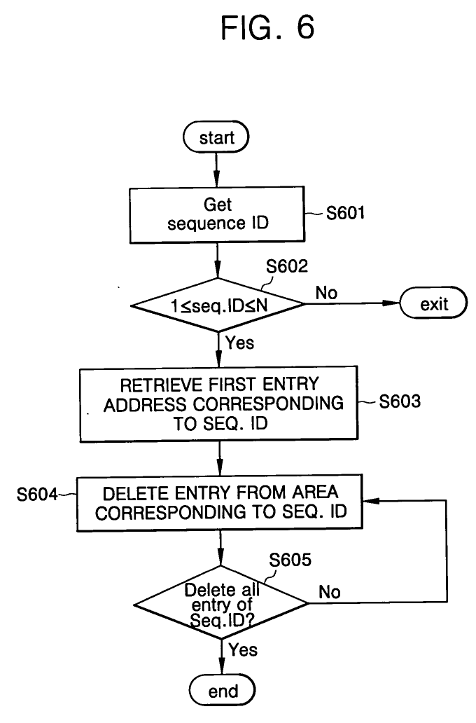

FIG. 6 is an operational flow chart relating to deletion of an entry from a TCAM by a method for managing a TCAM table according to the present invention.

The entries in each sequence that are constantly divided and distributed are added as in the cases of FIGS. 4 and 5, but are sometimes deleted. As such, there may be provided an exemplary case where, when the user intends to delete the classification rule considered not necessary anymore, the sequence ID and all of the entries included in the corresponding sequence ID should be accordingly deleted.

A deleting procedure is conducted to get the sequence ID of the entry to be deleted (S601), and to determine whether the corresponding sequence ID is within the range provided upon initialization of the TCAM (from 1 to N, where N is the number of the whole sequence IDs dividing the TCAM 200) (S602). If not within the range, the procedure is terminated.

If it is determined that the sequence ID of the entry to be requested to add is within the proper range, a process is conducted to retrieve an address of the first entry corresponding to the corresponding sequence ID (S603), and to delete the first entry from the corresponding area (S604). Since this case corresponds to the case wherein all entries in the corresponding sequence ID area are deleted, a process is conducted to determine whether all of the entries in the corresponding sequence ID area are deleted (S605), and the deleting operation for the separate entries is repeated. When all entries in the corresponding sequence ID are deleted, the procedure is terminated. In this case, entries with deleted sequence ID in TCAM 200 do not exist.

The present invention has an advantage in that a priority of the user rules for the entries in TCAM 200 that are defined by the user may be maintained so that, when required to establish range-match for port number in the rules for packet classification or filtering, a single sequence ID is provided for entries extended into plural ones, facilitating the management of TCAM 200.

While the invention has been described in conjunction with various embodiments, they are illustrative only. Accordingly, many alternatives, modifications and variations will be apparent to persons skilled in the art in light of the foregoing detailed description. The foregoing description is intended to embrace all such alternatives and variations falling with the spirit and broad scope of the appended claims.

What is claimed is:

1. A method for managing a ternary Content Addressable Memory (CAM), the method comprising the steps of:
dividing the ternary CAM into parts corresponding to a number of sequence identifiers (IDs) determined by a packet classification rule set by a system manager;
storing a packet having a priority set according to the packet classification rule in an entry storage area of the sequence IDs according to the priority; and
controlling the ternary CAM so that, when an entry storage area allocated to a sequence ID, wherein a new entry is intended to be added, is completely occupied, a corresponding sequence ID area is extended and the new entry is added thereto.

2. The method according to claim 1, wherein all entries in one sequence ID area have the same priority.

3. The method according to claim 1, wherein all sequence IDs in the dividing step have a same number of entries at initialization of the ternary CAM.

4. The method according to claim 1, wherein the dividing step includes determining the sequence IDs according to the packet classification rule such that a sequence ID is matched to a packet classification rule in a one-to-one correspondence relationship.

5. The method according to claim 1, wherein the dividing step is conducted so as to locate a sequence ID of a smaller number at an upper layer of the ternary CAM.

6. The method according to claim 1, wherein the number of sequence IDs is limited depending upon a capability of the ternary CAM.

7. The method according to claim 1, wherein the controlling step comprises:
when a new entry is added to a specific sequence ID of the ternary CAM, receiving a sequence ID input of the added entry and determining whether the received sequence ID input is within a range of the sequence ID provided upon initial dividing of the ternary CAM;
when the received sequence ID input is determined to be within the range, determining whether an empty space for addition of the new entry exists in the received sequence ID input; and
when it is determined that there is no empty space, retrieving a compensating sequence ID having an empty entry space located in closest proximity to the received sequence ID input, and adding the new entry to the received sequence ID input using the empty entry space in the compensating sequence ID.

8. The method according to claim 7, wherein the adding of the new entry comprises:
when the received sequence ID input is larger than the compensating sequence ID, sequentially moving all sequence ID areas existing in the received sequence ID input and the compensating sequence ID to an upper layer of the ternary CAM by use of the empty entry space in an area of the compensating sequence ID, and adding the new entry to an empty entry space newly generated in the received sequence ID input area in response to the movement.

9. The method according to claim 7, wherein the adding of the new entry comprises:
when the received sequence ID input is smaller than the compensating sequence ID, sequentially moving all sequence ID areas existing in the area between the received sequence ID input and the compensating sequence ID to a lower layer of the ternary CAM by use of the empty entry space in an area of the compensating sequence ID, and adding the new entry to an empty entry space newly generated in the received sequence ID input area in response to the movement.

10. The method according to claim 1, wherein the controlling step comprises:
when a packet classification rule is deleted by the system manager, deleting all entries in a sequence ID area corresponding to the deleted rule.

11. The method according to claim 10, wherein the step of deleting all entries in the sequence ID area comprises:
receiving the sequence ID of the added entry and determining whether the received sequence ID input is within a range which is provided in the dividing step; and
when the received sequence ID input is within the range which is provided in the dividing step, determining a location of a begin entry of the sequence ID, deleting a corresponding entry, and then repeating entry deletion until said all entries in the sequence ID area are completely deleted.

12. A method for managing a ternary Content Addressable Memory (CAM), the method comprising the steps of:
dividing the ternary CAM into parts corresponding to a number of sequence identifiers (IDs) determined by a packet classification rule set by a system manager;
storing a packet having a priority set according to the packet classification rule in an entry storage area of the sequence IDs according to the priority; and
when an entry storage area allocated to a sequence ID, wherein a new entry is intended to be added, is completely occupied, retrieving a compensating sequence ID having an empty entry space located in closest proximity to the sequence ID, moving in sequence all sequence ID areas existing in the received sequence ID input and the compensating sequence ID to one of an upper layer and a lower layer of the ternary CAM by use of the empty entry space of the compensating sequence ID, and adding the new entry to an empty entry space newly generated in an area of the received sequence ID input in response to the movement.

13. An apparatus for managing a ternary Content Addressable Memory (CAM), comprising:
a ternary CAM hardware configuration module for initializing the ternary CAM by dividing the ternary CAM into parts corresponding to a number of sequence identifiers (IDs) determined by a packet classification rule set by a system manager; and
a ternary CAM entry management module for storing a packet having a priority according to the packet classification rule in an entry storage area of a sequence ID according to the priority;
wherein, when an entry storage area allocated to the sequence ID where a new entry is intended to be added is completely occupied, a corresponding sequence ID area is extended and the new entry is added thereto, thereby controlling the ternary CAM.

14. The apparatus according to claim 13, wherein, in the ternary CAM hardware configuration module, all entries in one sequence ID area have the same priority.

15. The apparatus according to claim 13, wherein, in the ternary CAM hardware configuration module, determination of the sequence ID according to the packet classification rule is conducted in such a manner that a sequence ID is matched to a packet classification rule in a one-to-one correspondence relationship.

16. The apparatus according to claim 13, wherein, when a new entry is added to a specific sequence ID of the ternary CAM, the ternary CAM entry management module receives an inputted sequence ID of the added packet entry, determines whether the inputted sequence ID is within a range provided upon initial division of the ternary CAM and whether an empty space where the new entry is to be added exists in the inputted sequence ID; and
when it is determined that no empty space exists, the ternary CAM entry management module retrieves a compensating sequence ID having an empty entry space located in closest proximity to said inputted sequence ID, and adds the new entry intended to be added to the inputted sequence ID by using the empty entry space in the compensating sequence ID.

17. The apparatus according to claim 13, wherein, when a packet classification rule is deleted by the system manager, the TCAM entry management module deletes all entries in an area of the sequence ID corresponding to the deleted rule.

18. The apparatus according to claim 17, wherein the TCAM entry management module deletes the entries in the area of the sequence ID by receiving the sequence ID of the added packet entry, determining whether an inputted sequence ID is within a range provided upon division of the ternary CAM, and when the inputted sequence ID is within the range, determining a location of a begin entry of the sequence ID, deletes the corresponding entry, and repeats entry deletion until said all entries in the sequence ID are completely deleted.

19. The apparatus according to claim 13, further comprising a TCAM entry lookup module for generating search keys and providing the generated search keys to the ternary CAM, and for implementing a lookup by using retrieval result data received from the ternary CAM in response to generation of the search keys.

20. An apparatus for managing a ternary content addressable memory (CAM), comprising:
a TCAM hardware configuration module for initializing the ternary CAM by dividing the TCAM into parts corresponding to a number of sequence IDs determined by a packet classification rule set by a system manager; and
a TCAM entry management module for storing a packet having a priority according to the packet classification rule in an entry storage area of a sequence ID according to the priority; and
wherein, when an entry storage area allocated to the sequence ID where a new entry is intended to be added is completely occupied, the TCAM entry management module retrieves a compensating sequence ID having an empty entry space located in closest proximity to said sequence ID, moves in sequence all sequence ID areas existing in an inputted sequence ID and the compensating sequence ID to one of an upper layer and a lower layer of the ternary CAM by use of the empty entry space in an area of the compensating sequence ID, and adds the new entry to an empty entry space newly generated in an area of the inputted sequence ID in response to the movement.
